(19) United States
(12) Patent Application Publication
(10) Pub. No.: US 2026/0333716 A1
(43) Pub. Date: Oct. 22, 2026

(54) CAPACITOR ARRAY FORMATION USING SINGLE ETCH PROCESS

(71) Applicant: Taiwan Semiconductor Manufacturing Company, Ltd., Hsinchu (TW)

(72) Inventors: Meng-Hsien Lin, Tainan City (TW); Hsing-Chih Lin, Tainan City (TW); Wei-Chih Weng, Tainan City (TW); Kuan-Hua Lin, New Taipei City (TW); Jen-Cheng Liu, Hsin-Chu City (TW); Dun-Nian Yaung, Taipei City (TW)

(21) Appl. No.: 19/723,715

(22) Filed: Jun. 29, 2026

Related U.S. Application Data
(62) Division of application No. 18/362,101, filed on Jul. 31, 2023.

(51) Int. Cl. H10D 1/00; H10D 1/68; H10D 84/00; H10W 20/00; H10W 20/40; H10W 20/42

(52) U.S. Cl. CPC H10D 1/042; H10D 1/716; H10D 84/212; H10W 20/089; H10W 20/42; H10W 20/496

(57) ABSTRACT

In some embodiments, the present disclosure relates to an integrated device, including a substrate; an interconnect structure disposed over the substrate, the interconnect structure including an dielectric; a first bottom electrode structure disposed in the dielectric, the first bottom electrode structure having a first width as measured between outer sidewalls of the first bottom electrode structure and a first depth as measured from an upper surface of the dielectric; and a second bottom electrode structure disposed in the dielectric and spaced apart from the first bottom electrode structure, the second bottom electrode structure having a second width as measured between outer sidewalls of the second bottom electrode structure and a second depth as measured from the upper surface of the dielectric; where the first width is greater than the second width and the first depth is greater than the second depth.

### REFERENCE TO RELATED APPLICATION

This Application is a Divisional of U.S. Application number Ser. No. 18/362,101, filed on Jul. 31, 2023, the contents of which are hereby incorporated by reference in their entirety.

### BACKGROUND

Many modern day electronic devices include capacitors. The capacitance of a capacitor depends on multiple factors, including the surface area of a first and second electrode, the proximity of the first and second electrode, and the permittivity of a dielectric between the first and second electrode. The surface area of the first and second electrodes may be formed in horizontal formations across the electronic device, in vertical formations, or in both formations depending on the target capacitance and availability of space in the electronic device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip having a plurality of capacitors with bottom electrode structures of different depths and widths.

FIG. 2 illustrates a cross-sectional view of some additional embodiments of an integrated chip having a plurality of capacitors with bottom electrode structures of different depths and widths coupled to a plurality of wires beneath the capacitors.

FIGS. 3A-3D illustrate cross-sectional views of some additional embodiments of an integrated chip having capacitors with a plurality of bottom electrode structures of different depths and widths.

FIGS. 4A-4C illustrate cross-sectional views and a graph of some additional embodiments of an integrated chip having capacitors with a plurality of bottom electrode structures of different depths and widths.

FIGS. 5-11 illustrate cross-sectional views of some embodiments of a method of forming an integrated chip having a plurality of capacitors with bottom electrode structures of different depths and widths.

FIG. 12 illustrates a flow diagram of some embodiments of a method of forming an integrated chip having a plurality of capacitors with bottom electrode structures of different depths and widths.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Capacitors are used for a variety of purposes in integrated devices, including memory, image processing, and sensing apparatus. The capacitance of a capacitor is dependent on multiple factors, including the surface area of a first and second electrode, the proximity of the first and second electrode, and the permittivity of a dielectric between the first and second electrode. When formed using back-end-of-line (BEOL) processes, capacitors may be formed having a surface area spread across a dielectric, with the surface area confined in trenches etched into the dielectric, or a combination of both of these distributions. Capacitors spread horizontally across the dielectric may be patterned using a single etching process and may have a large variety of capacitances without increasing the number of etches used, though they use a larger surface area of the integrated chip than a vertical capacitor. Vertical capacitors (e.g., capacitors formed in trenches) extend through the integrated device vertically, and therefore use a smaller surface area of the integrated chip than a horizontally spread capacitor, which may result in a greater density of capacitors fitting into a single layer of the integrated device. However, the method of forming vertical capacitors typically uses separate masks and etching steps to form trenches of different depths to form the vertical capacitors in, resulting in increased costs and low flexibility. Capacitors utilizing a combination of both horizontal and vertical structures increase the flexibility of the capacitor array, but lower the density of capacitor that may fit in a single layer of the integrated device. A capacitor array with the high density of capacitors available to arrays utilizing vertical capacitors, a low number of masking and etching steps, and the flexibility of capacitances available to arrays utilizing horizontally spread capacitors is desirable.

The present disclosure provides an integrated device comprising capacitors with bottom electrode structures of different widths and different depths. The capacitors are formed by etching a plurality of trenches with multiple depths into a dielectric layer. The plurality of trenches are etched using a single etching process and a masking layer with openings of varying widths. The widths of the openings in the masking layer result in the etch rate of the plurality of trenches to vary, due to the etch-loading effect. The differences in etch rate leads to the plurality of trenches having different depths. Capacitors are then formed in the plurality of trenches. Capacitors formed in the trenches with greater depths and widths have a greater surface area. The difference in surface area of the capacitors results in the capacitors having different capacitances without having large variations in the horizontal surface area used for each capacitor or multiple etch steps for the different depths. Therefore, the presented method is more cost effective and flexible than related methods of capacitor production.

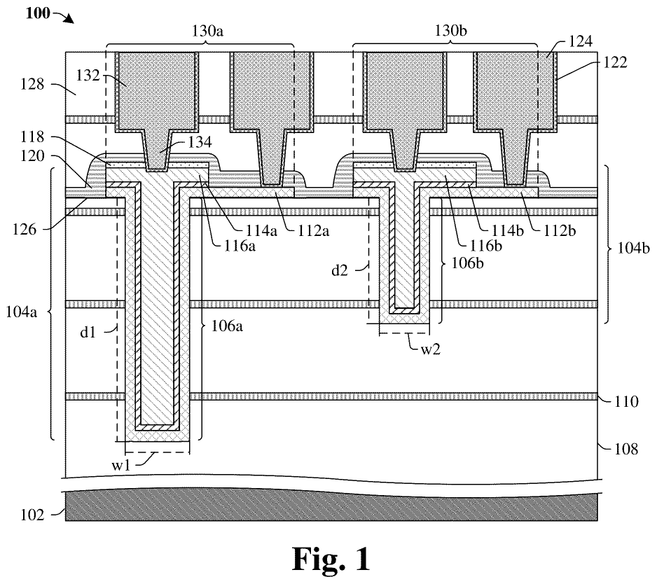

FIG. 1 illustrates a cross-sectional view 100 of some embodiments of an integrated chip having a plurality of capacitors with bottom electrode structures of different depths and widths.

An interconnect structure comprising an interlayer dielectric 108 is formed over a substrate 102. A first bottom electrode 112a, and a second bottom electrode 112b are formed over an upper surface 126 of the interlayer dielectric 108. In some embodiments, the first bottom electrode 112a and the second bottom electrode 112b are separated by a passivation layer 120 and are part of a first capacitor 104a and a second capacitor 104b, respectively.

A first dielectric 114a and a first top electrode 116a overly the first bottom electrode 112a. The first dielectric 114a separates the first bottom electrode 112a from the first top electrode 116a. A second dielectric 114b and a second top electrode 116b overly the second bottom electrode 112b. The second dielectric 114b separates the second bottom electrode 112b from the second top electrode 116b.

The first bottom electrode 112a has a first width w1 measured between outer sidewalls of the first bottom electrode 112a. The first bottom electrode 112a further has a first depth d1 measured from an upper surface 126 of the interlayer dielectric 108. The second bottom electrode 112a has a second width w2 measured between outer sidewalls of the second bottom electrode 112b. The second bottom electrode 112b further has a second depth d2 measured from an upper surface 126 of the interlayer dielectric 108. The first width w1 is greater than the second width w2, and the first depth d1 is greater than the second depth d2. The difference between the first depth d1 and the second depth d2 may be attributed to the difference in a magnitude of the etch-loading effect that occurs during an etching process before the formation of the first and second bottom electrodes 112a, 112b. The difference in the magnitude of the etch-loading effect is a result of the difference between the first width w1 and the second width w2, where a greater width results in a greater etch depth.

In some embodiments, the first width w1 is measured between outer sidewalls of a first bottom electrode structure 106a of the first bottom electrode 112a. Similarly, the second width w2 is measured between outer sidewalls of a second bottom electrode structure 106b of the second bottom electrode 112b. In further embodiments, the first depth d1 is measured from the upper surface 126 of the interlayer dielectric 108 to a bottom surface of the first bottom electrode structure 106a, and the second depth d2 is measured from the upper surface 126 of the interlayer dielectric 108 to a bottom surface of the second bottom electrode structure 106b. The first bottom electrode structure 106a extends from a first horizontal portion 130a of the first bottom electrode 112a overlying the upper surface 126 of the interlayer dielectric 108. The second bottom electrode structure 106b extends from a second horizontal portion 130b of the second bottom electrode 112b overlying the upper surface 126 of the interlayer dielectric 108. In some embodiments, the first horizontal portion 130a has a first area and the second horizontal portion 130b has a second area different from the first area. In some embodiments, the first bottom electrode structure 106a extends through one or more etch stop layers 110. In further embodiments, the second bottom electrode structure 106b does not extend through the one or more etch stop layers 110. In some embodiments, the first bottom electrode structure 106a and the second bottom electrode structure 106b are part of a single capacitor and are electrically coupled by a metal line (not shown) running continuously between the first bottom electrode structure 106a and the second bottom electrode structure 106b.

An anti-reflect coating (ARC) 118 overlies the first top electrode 116a and the second top electrode 116b. A passivation layer 120 conformally overlies the ARC 118, the first top electrode 116a, the second top electrode 116b, and the upper surface 126 of the interlayer dielectric 108. Additional dielectric layers 128 of the interlayer dielectric 108 are arranged above the passivation layer 120. A first wire level 124 is arranged in the additional dielectric layers 128. The first wire level 124 comprises wires 132 and vias 134 that are electrically coupled to the first capacitor 104a and the second capacitor 104b. In some embodiments, the first wire level 124 is separated from the additional dielectric layers 128 of the interlayer dielectric 108 by first barrier layers 122. In some embodiments, the first barrier layer 122 may comprise a metal-nitride such as titanium (Ti), tantalum (Ta), titanium nitride (TiN), tantalum nitride (TaN), the like, or a combination of the foregoing. In some embodiments, upper surfaces of the first bottom electrode 112a and the second bottom electrode 112b are electrically coupled to wires in the first wire level 124. In some embodiments, the upper surfaces are contacting the vias or the first barrier layers 122 surrounding the vias that are contacting the first wire level 124.

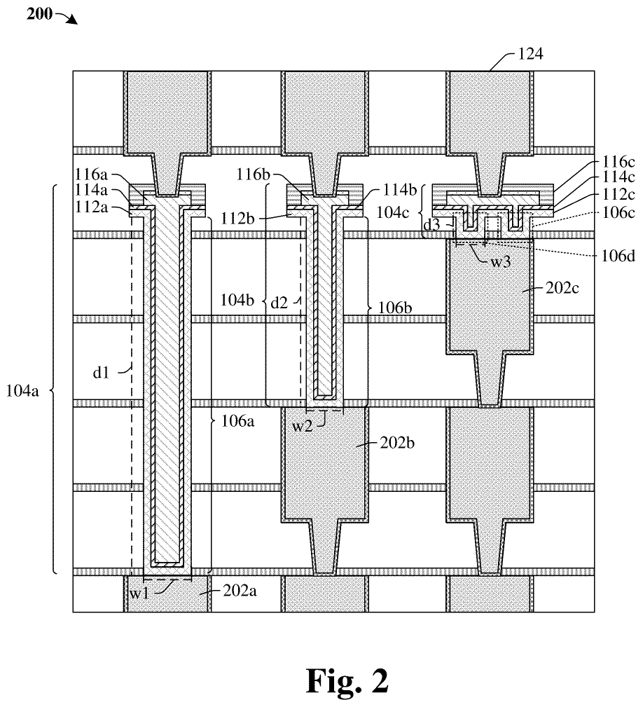

FIG. 2 illustrates a cross-sectional view 200 of some additional embodiments of an integrated chip having a plurality of capacitors with bottom electrode structures of different depths and widths coupled to a plurality of wires beneath the capacitors.

In some embodiments, the bottom surfaces of the first bottom electrode structure 106a and the second bottom electrode structure 106b are contacting second wire levels 202a, 202b, 202c beneath the bottom surfaces. By using the first wire level 124 to contact the first top electrode 116a and the second wire levels 202a, 202b, 202c to contact the first bottom electrode structure 106a, the embodiment reduces the horizontal area of the first capacitor 104a used to connect both electrodes to the first wire level 124. Lowering the horizontal area used by individual capacitors may increase the density of capacitors in the integrated chip.

In some embodiments, a third capacitor 104c may have a third bottom electrode structure 106c and a fourth bottom electrode structure 106d extending to the second wire levels 202a, 202b, 202c. A third dielectric 114c separates the third bottom electrode structure 106c and the fourth bottom electrode structure 106d from a third top electrode 116c. The third bottom electrode structure 106c and the fourth bottom electrode structure 106d both add to the capacitance of the third capacitor 104c. The variance in the number of bottom electrode structures extending from the first, second and third bottom electrodes 112a, 112b, 112c expands the variety of different profiles that may achieve similar capacitances, and extends the range of capacitances that may be provided using this method.

In some embodiments, the first bottom electrode structure 106a may have the first width w1 and the first depth d1, the second bottom electrode structure 106b may have the second width w2 and the second depth d2, and the third and fourth bottom electrode structures 106c, 106d may have a third width w3 and a third depth d3. The difference in depths of the bottom electrode structures correlates to the difference in widths of the bottom electrode structures. That is, the first bottom electrode structure 106a has the first width w1 which is greater than the second width w2 of the second bottom electrode structure 106b, and also has the first depth d1 which is greater than the second depth d2 of the second bottom electrode structure 106b. The difference in widths w1, w2 results in a difference in the magnitude of etch-loading effects during the forming of the first and second capacitor 104a, 104b, leading to different etch rates and different depths d1, d2 for the first and second capacitor 104a, 104b. Therefore, the difference between the first depth d1 and the second depth d2 is a result of the difference between the first width w1 and the second width w2. The third and fourth bottom electrode structures 106c, 106d have the third width w3 that is less than the second width w2, and therefore have the third depth d3 which is less than the second depth d2.

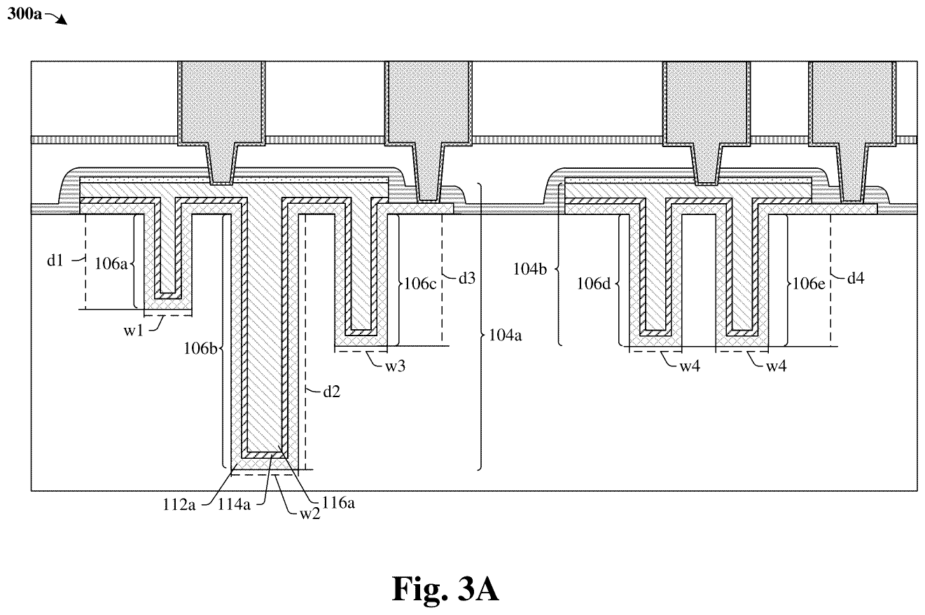

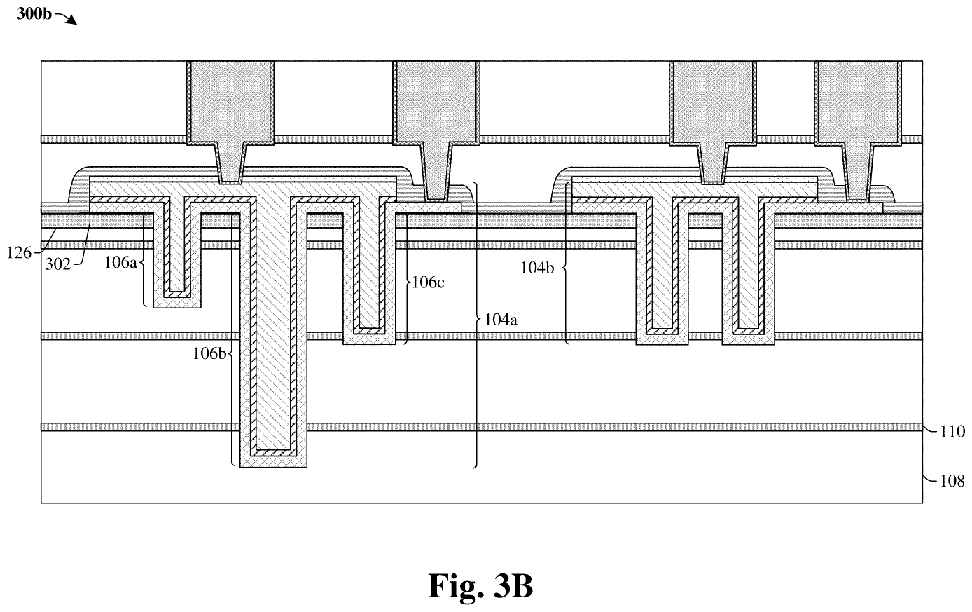

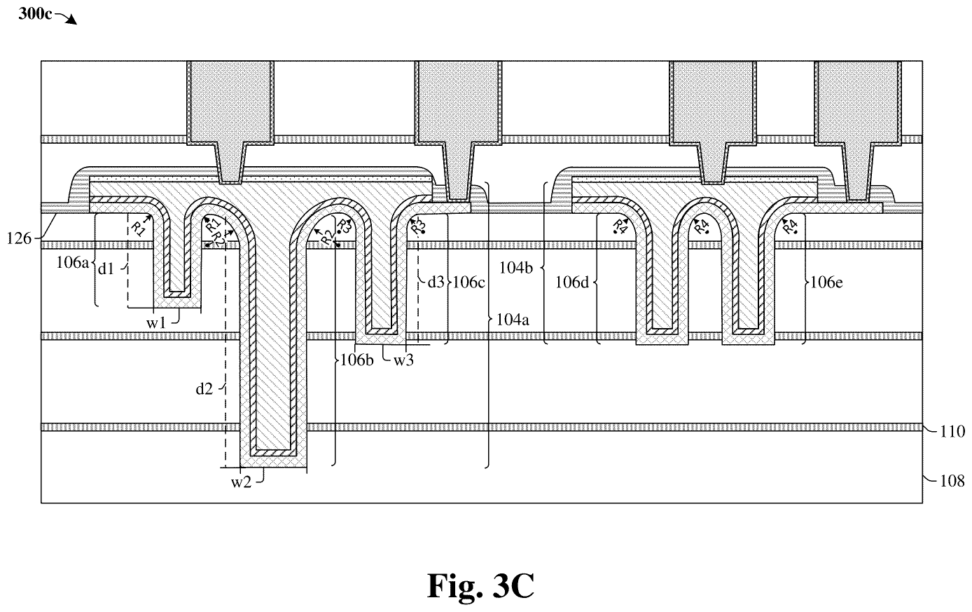

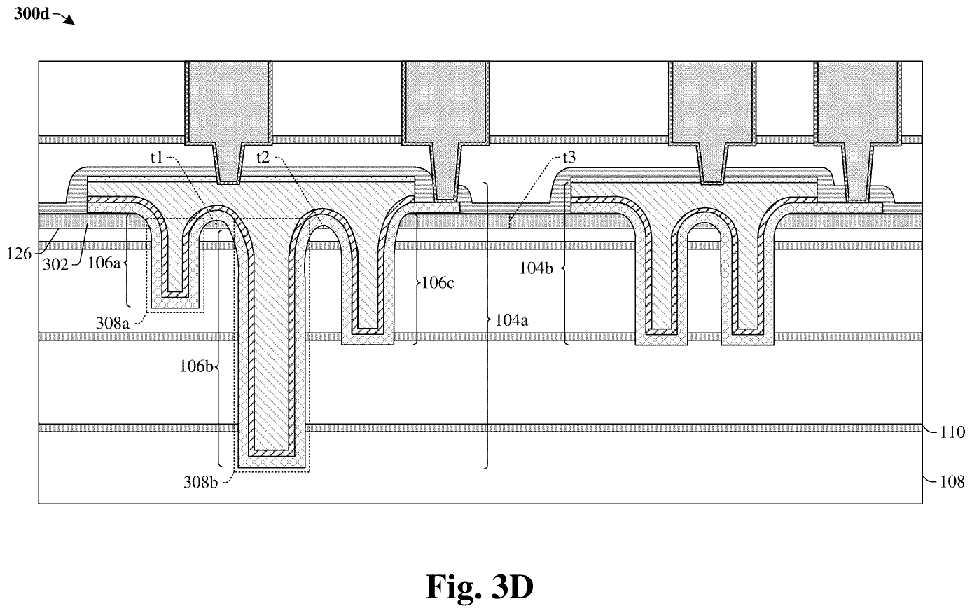

FIGS. 3A-3D illustrate some additional embodiments 300a-300d of an integrated chip having capacitors with a plurality of bottom electrode structures of different depths and widths.

As shown in the cross-sectional view 300a of FIG. 3A, in some embodiments, the first capacitor 104a may have the first bottom electrode structure 106a, the second bottom electrode structure 106b, and the third bottom electrode structure 106c. The first bottom electrode structure 106a, the second bottom electrode structure 106b, and the third bottom electrode structure 106c may respectively have the first depth d1, the second depth d2, and a third depth d3, and the first width w1, the second width w2, and a third width w3. The variance in the etch-loading effect during the etching process used before forming the first bottom electrode 112a results in the bottom electrode structure with a least width having a least depth and the bottom electrode structure with a greatest width having a greatest depth. For example, the first width w1 is less than the second width w2 and the third width w3. The second width w2 is greater than the third width w3. Therefore, the first bottom electrode structure 106a has the least width, resulting in the first depth d1 being the least depth (e.g., lower than the second depth d2 and the third depth d3). Further, the second bottom electrode structure 106b has the greatest width, resulting in the second depth d2 being the greatest depth (e.g., greater than the first depth d1 and the third depth d3).

In further embodiments, the second capacitor 104b may comprise the fourth bottom electrode structure 106d and a fifth bottom electrode structure 106e. The fourth bottom electrode structure 106d and the fifth bottom electrode structure may have a fourth width w4. That is, the fourth bottom electrode structure 106d may have a fourth width w4 that is substantially equal to the width of the fifth bottom electrode structure. The widths of the fourth bottom electrode structure 106d and the fifth bottom electrode structure 106e being substantially equal results in the depths of the fourth bottom electrode structure 106d and the fifth bottom electrode structure 106e being substantially equal. The fourth bottom electrode structure 106d and the fifth bottom electrode structure 106e have a fourth depth d4.

The first capacitor 104a and the second capacitor 104b may be part of a plurality of capacitors, which may respectively have a plurality of bottom electrode structures with depths different to the first, second, third, and fourth depths d1, d2, d3, d4. In some embodiments, the first bottom electrode structure 106a of the plurality of bottom electrode structures has a least width and a least depth. In further embodiments, bottom electrode structures of the plurality of bottom electrode structures with progressively greater widths up to a greatest width have progressively greater depths up to a greatest depth. In further embodiments, a second bottom electrode structure (e.g., the second bottom electrode structure 106b) of the plurality of bottom electrode structures has a median depth of the plurality of different depths and a median width of the plurality of different widths. A plurality of top electrodes extend between inner sidewalls of the plurality of bottom electrode structures.

In some embodiments, the first width w1 is between 80 nanometers and 120 nanometers, 95 and 105 nanometers, or the like. In some embodiments, the first depth d1 is between 500 nanometers and 800 nanometers, 625 and 675 nanometers, or the like. In some embodiments, the second width w2 is between 130 nanometers and 170 nanometers, 145 and 155 nanometers, or the like. In some embodiments, the second depth d2 is between 1000 nanometers and 1300 nanometers, 1100 and 1150 nanometers, or the like. In some embodiments, the third width w3 is between 90 nanometers and 130 nanometers, 105 and 115 nanometers, or the like. In some embodiments, the third depth d3 is between 750 nanometers and 1050 nanometers, 900 and 950 nanometers, or the like. In other embodiments, different ranges of widths and depths are used for one or more bottom electrode structures, and result in capacitors with different capacitances and cross-sectional profiles.

As shown in the cross-sectional view 300b of FIG. 3B, a hard mask 302 may be present over the upper surface 126 of the interlayer dielectric 108. In some embodiments, the hard mask 302 is or comprises silicon nitride (Si₃N₄) or the like. The hard mask 302 surrounds the plurality of bottom electrode structures of the first bottom electrode 112a and the second bottom electrode 112b. In some embodiments, the hard mask extends between the plurality of bottom electrode structures, including between the first bottom electrode structure 106a and the second bottom electrode structure 106b. In some embodiments, the hard mask 302 is left in place after the etching process used to form first and second trenches 308a, 308b (See FIG. 3D) in which the first and second bottom electrode structures 106a, 106b are subsequently formed, and has inner sidewalls that may correspond in a one-to-one fashion with the bottom electrodes. If present, this one-to-one correspondence evidences that the trenches in which the bottom electrodes were formed by a single etch using the hard mask 302, and the different depths of the trenches can evidence etch-loading effects and, hence, a very efficient manufacturing process.

As shown in the cross-sectional view 300c of FIG. 3C, in some embodiments, outer sidewalls of the first bottom electrode 112a in the first bottom electrode structure 106a, the second bottom electrode structure 106b, and the third bottom electrode structure 106c may have different curvatures proximate to the upper surface 126 of the interlayer dielectric 108. For example, a first maximum radius of curvature R1 of the first bottom electrode structure 106a may be less than a second maximum radius of curvature R2 of the second bottom electrode structure 106b. Further, a third maximum radius of curvature R3 of the third bottom electrode structure 106c may be less than the second maximum radius of curvature R2 of the second bottom electrode structure 106b but greater than the first maximum radius of curvature R1 of the first bottom electrode structure 106a. In some embodiments, the radii of curvature may vary over corners of the bottom electrode structures. That is, the first bottom electrode structure 106a may have a radius of curvature at one position proximate to the upper surface 126 of the interlayer dielectric 108 that is less than the first maximum radius of curvature R1.

In some embodiments, the maximum radii of curvature R1, R2, R3 correlate to the widths w1, w2, w3 of the plurality of bottom electrode structures 106a, 106b, 106c, such that the bottom electrode structure with the least width (e.g., the first bottom electrode structure 106a) has the lowest maximum radius of curvature (e.g., the first maximum radius of curvature R1). Further, the bottom electrode structure with the greatest width (e.g., the second bottom electrode structure 106b) has the highest maximum radius of curvature (e.g., the third maximum radius of curvature R3). The fourth bottom electrode structure 106d and the fifth bottom electrode structure 106e of the second capacitor 104b have substantially equal widths w4, and therefore have substantially equal maximum radii of curvature R4. The difference in maximum radii of curvature R1, R2, R3, R4 between the plurality of bottom electrode structures may be the result of differing etch rates between the trenches 308a, 308b (See FIG. 3D) formed prior to the formation of the bottom electrode structures.

As shown in the cross-sectional view 300d of FIG. 3D, in some embodiments, thicknesses of the hard mask 302 directly between the first, second, and third bottom electrode structures 106a, 106b, 106c are lower than the thickness of the hard mask 302 between the first capacitor 104a and the second capacitor 104b. For example, a first thickness t1 of the hard mask 302 measured between the first bottom electrode structure 106a and the second bottom electrode structure 106b is less than a second thickness t2 of the hard mask 302 measured between the first capacitor 104a and the second capacitor 104b. Further, a third thickness t3 of the hard mask 302 measured between the second bottom electrode structure 106b and the third bottom electrode structure 106c is less than the first thickness t1 and the second thickness t2.

The difference in thicknesses between the first thickness t1, the second thickness t2, and the third thickness t3 is based on the etch-loading effects present in the etching of the first and second trenches 308a, 308b surrounding the first thickness t1 and the second thickness t2. The etch rate of the interlayer dielectric 108 and the hard mask 302 is lower for a first trench 308a filled by the first bottom electrode structure 106a than a second trench 308b filled by the second bottom electrode structure 106b. The difference in etch rates is due to the first trench 308a having a first width w1 less than the second width w2 of the second trench 308b. The width w1 being less than the width w2 results in a lower amount of etchant reacting with the hard mask and the interlayer dielectric in the first trench 308a, which further results in the removal of less material near the opening of the first trench 308a compared to the second trench 308b. The removal of a greater amount of material at the opening of the second trench 308b may result in upper portions of the hard mask being removed. The portions of the hard mask 302 directly between the plurality of bottom electrode structures (e.g., between the first bottom electrode structure 106a and the second bottom electrode structure 106b) may be etched from multiple directions, which may lead to a greater amount of the hard mask being etched and lead to a decrease in the thickness of the hard mask 302 at those positions.

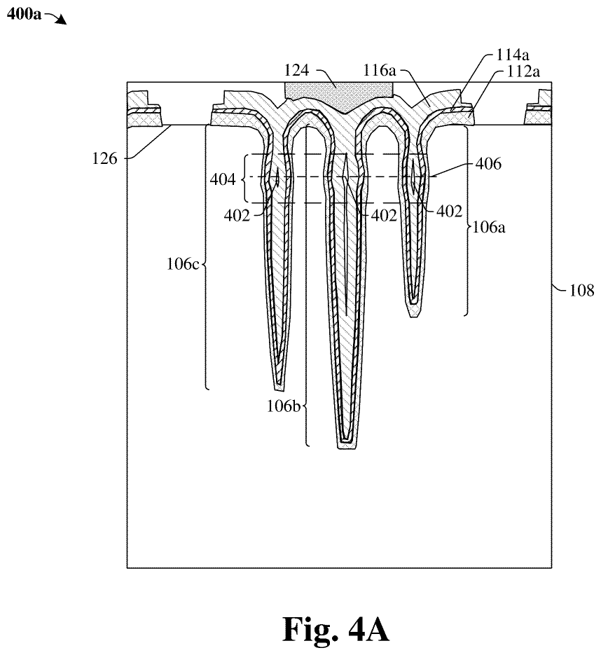

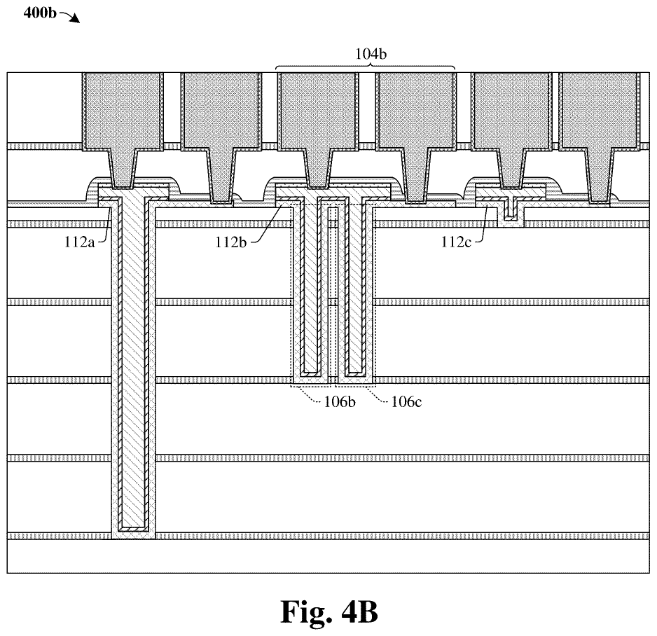

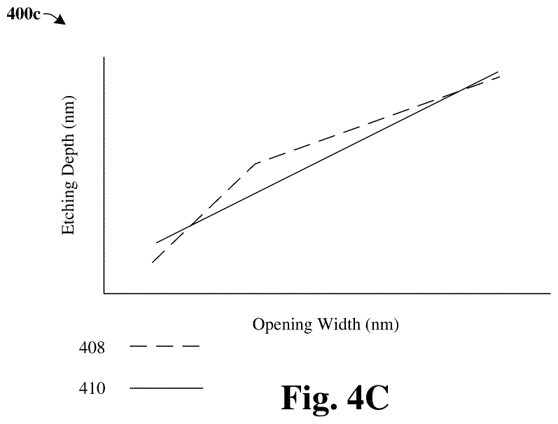

FIGS. 4A-4C illustrate cross-sectional views 400a, 400b and a graph 400c of some additional embodiments of an integrated chip having capacitors with a plurality of bottom electrode structures of different depths and widths.

As shown in FIG. 4A, in some embodiments, gaps 402 may be present in the plurality of bottom electrode structures. In some embodiments, the plurality of bottom electrode structures may have bulbs 404 where the width of the plurality of bottom electrode structures is at a local maximum. The bulbs 404 are segments of the plurality of bottom electrode structures where the widths of the bottom electrode structures increase up to a middle line 406 going through the local maxima of the widths. The widths then decrease back to a width that the bottom electrode structures had before the widths began to increase at the bulbs 404. The bulbs 404 in the plurality of bottom electrode structures are proximate to the upper surface 126 of the interlayer dielectric 108. In further embodiments, the middle line 406 of the bulbs 404 is at a depth below the upper surface 126 of the interlayer dielectric 108 that is independent of the depths of the plurality of bottom electrode structures. That is, the middle line 406 extends through the maximum width of the bulbs 404 in the first bottom electrode structure 106a, the second bottom electrode structure 106b and the third bottom electrode structure 106c, and is substantially parallel to the upper surface 126 of the interlayer dielectric 108.

As shown in FIG. 4B, in some embodiments, the second capacitor 104b may have a second bottom electrode structure 106b and a third bottom electrode structure 106c extending beneath the first wire level 124. The variance in the number of bottom electrode structures extending from the first, second and third bottom electrodes 112a, 112b, 112c expands the variety of different profiles that may achieve similar capacitances, and extends the range of capacitances that may be provided using this method of fabrication.

As shown in FIG. 4C, there is a positive correlation between the etching depth and the opening width during the etching process. That is, for a range of opening widths, trenches with a greater opening width will have a greater etching depth for the same etching process. Line 408 shows the etching depths and opening widths of FIG. 4A, while line 410 shows a trendline of the data shown in line 408.

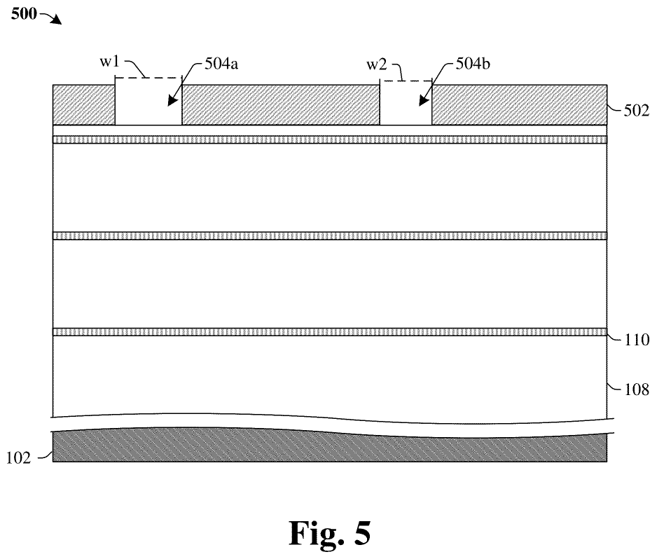

FIGS. 5-11 illustrate cross-sectional views 500-1100 of some embodiments of a method of forming an integrated chip having a plurality of capacitors with bottom electrode structures of different depths and widths. Although FIGS. 5-11 are described in relation to a method, it will be appreciated that the structures disclosed in FIGS. 5-11 are not limited to such a method, but instead may stand alone as structures independent of the method.

As shown in cross-sectional view 500 of FIG. 5, the substrate 102 is provided. The interlayer dielectric 108 is on the substrate 102, and in some embodiments is periodically interleaved with the etch stop layers 110. A first masking layer 502 is formed on the interlayer dielectric 108. In some embodiments, the first masking layer 502 is a photoresist formed using a spin-on process. In other embodiments, the first masking layer 502 is a hard mask 302 formed using one of chemical vapor deposition (CVD), physical vapor deposition (PVD), atomic layer deposition (ALD), some other suitable deposition process, or a combination of the foregoing. The first masking layer 502 is then patterned, resulting in a first opening 504a and a second opening 504b. In some embodiments, the first masking layer 502 is patterned using photolithography. The first opening has the first width w1 and the second opening has the second width w2 that is less than the first width w1.

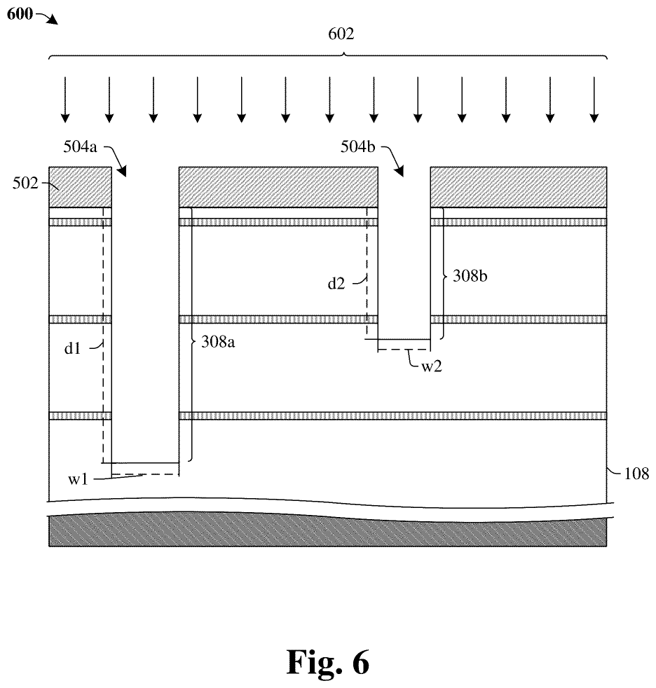

As shown in cross-sectional view 600 of FIG. 6, a first etching process 602 is performed. During the first etching process 602, the interlayer dielectric 108 is etched in the regions that are exposed by the first opening 504a and the second opening 504b in the first masking layer 502. In some embodiments, first etching process 602 may be a dry etch such as a plasma etch or the like. The first etching process 602 results in a first trench 308a formed beneath the first opening 504a and a second trench 308b formed beneath the second opening 504b. The first trench 308a has the first width w1 and is etched to the first depth d1, and the second trench 308b has the second width w1 and is etched to the second depth d2. The second depth d2 is less from the first depth d1 due to a difference in the etch rate in the first and second trenches 308a, 308b. The difference in etch rates is due to the second width w2 being less from the first width w1. The lower width of the second trench 308b results in less etchant reaching the bottom of the second trench 308b compared to the amount of etchant that may reach the bottom of the first trench 308a during the etching process. As the etch rates of the first trench 308a and the second trench 308b are respectively dependent on the width of the first opening 504a and the second opening 504b, the first trench 308a and the second trench 308b may be formed with different depths during a single etching process and using the same mask.

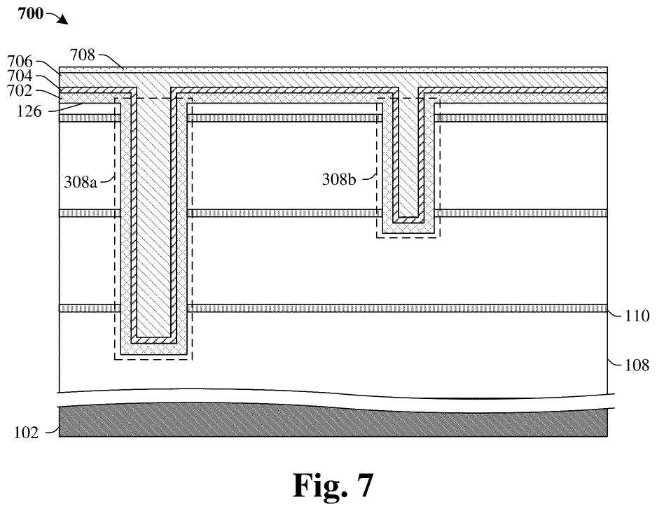

As shown in cross-sectional view 700 of FIG. 7, a first conformal electrode layer 702, a conformal dielectric 704, a second conformal electrode layer 706, and a conformal ARC layer 708 are deposited over the upper surface 126 of the interlayer dielectric 108. In some embodiments, the first conformal electrode layer 702, the conformal dielectric 704, the second conformal electrode layer 706, and the conformal ARC layer 708 may be deposited using one of CVD, PVD, ALD, some other suitable deposition process, or a combination of the foregoing. In some embodiments, the first masking layer 502 (see FIG. 6) is removed prior to the formation of the first conformal electrode layer 702. In other embodiments, the first masking layer 502 is a hard mask and is not removed before forming the first conformal electrode layer 702. The first conformal electrode layer 702, the conformal dielectric 704, and the second conformal electrode layer 706 extend in to the first trench 308a and the second trench 308b. The conformal dielectric 704 overlies the first conformal electrode layer 702 and separates the first conformal electrode layer 702 from the second conformal electrode layer 706. In some embodiments, the first conformal electrode layer 702 and the second conformal electrode layer 706 are or comprise one of copper (Cu), titanium (Ti), titanium nitrate (TiN), tungsten (W), aluminum (Al), tantalum nitrate (TaN), the like, or any combination of the foregoing. In some embodiments, the conformal dielectric 704 is or comprises one of silicon oxide (SiO₂), silicon nitride (Si₃N₄), a high-k dielectric, the like, or some combination of the foregoing.

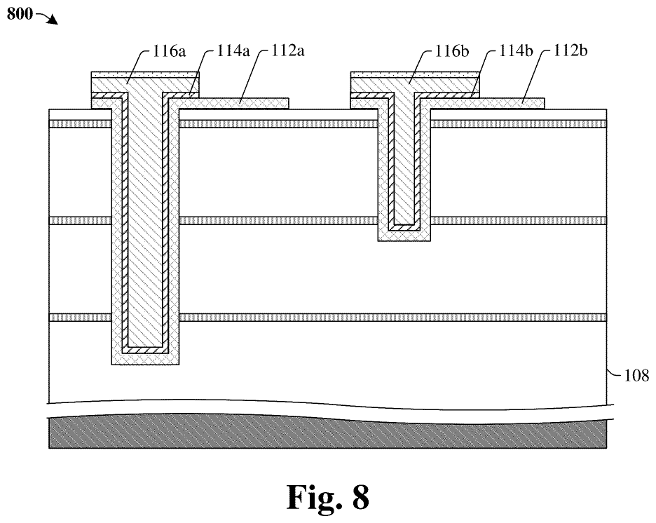

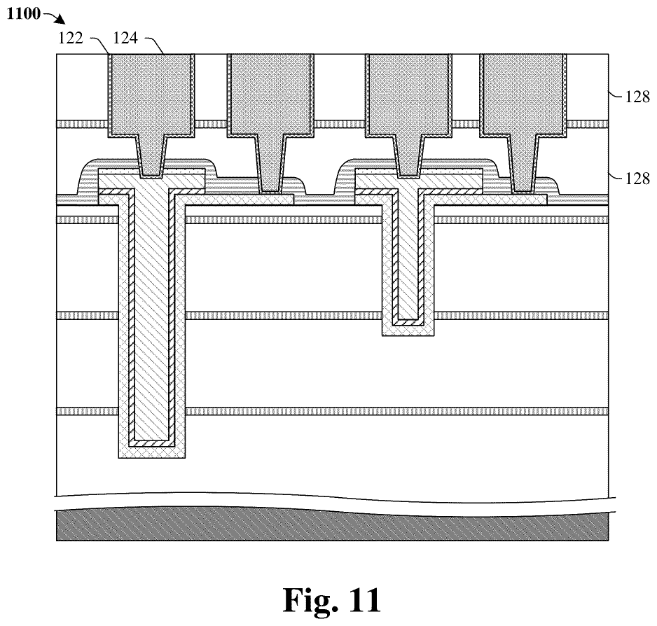

As shown in cross-sectional view 800 of FIG. 8, the first conformal electrode layer 702, the conformal dielectric 704 (see FIG. 7), the second conformal electrode layer 706 (see FIG. 7), and the conformal ARC layer 708 (see FIG. 7) are etched, resulting in the first bottom electrode 112a, the second bottom electrode 112b, the first dielectric 114a, the second dielectric 114b, the first top electrode 116a, and the second top electrode 116b. In some embodiments, etch may be a plasma etch or the like. In some embodiments, a portion of the upper surfaces of the first bottom electrode 112a and the second bottom electrode 112b are exposed and will be coupled to the first wire level 124 (see FIG. 1) above the first bottom electrode 112a as shown in later steps (see FIG. 11). In other embodiments, the upper surfaces of the first bottom electrode 112a and the second bottom electrode 112b are completely covered by the first dielectric 114a and the second dielectric 114b. Further, bottom surfaces of the first bottom electrode 112a and the second bottom electrode 112b are formed such that they contact the second wire levels 202a, 202b, 202c (see FIG. 2) below the bottom electrodes.

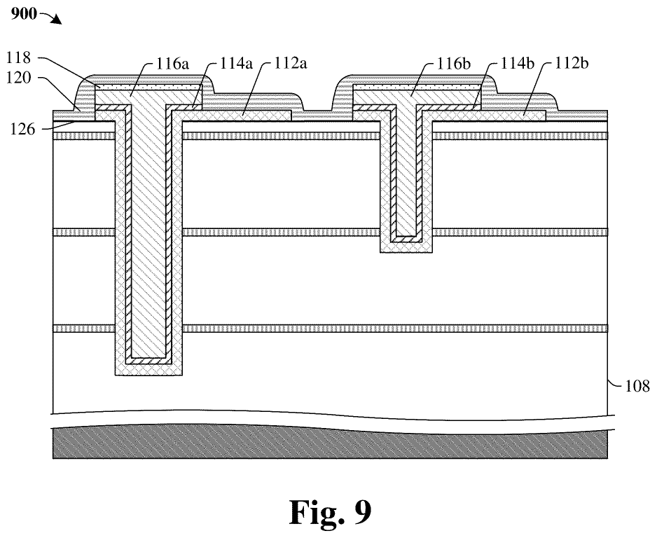

As shown in cross-sectional view 900 of FIG. 9, a passivation layer 120 is deposited over the upper surface 126 of the interlayer dielectric 108. The passivation layer 120 may be deposited using CVD, PVD, ALD, some other suitable deposition process, or a combination of the foregoing. The passivation layer 120 conformally overlies the ARC 118, the first and second bottom electrodes 112a, 112b, the first and second dielectric 114a, 114b, the first and second top electrodes 116a, 116b, and the upper surface 126 of the interlayer dielectric 108.

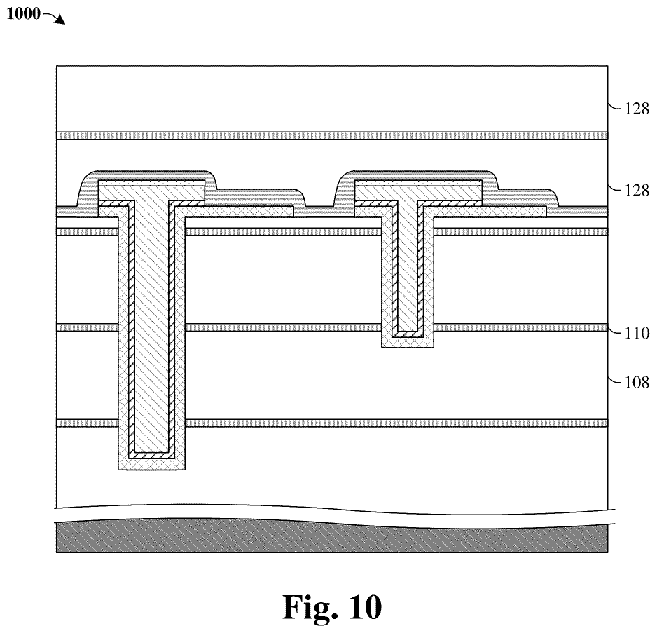

As shown in the cross-sectional view 1000 of FIG. 10, additional dielectric layers 128 are formed over the upper surface of the interlayer dielectric 108. In some embodiments, the additional dielectric layers 128 comprise a same material as the interlayer dielectric 108. In some embodiments, the additional dielectric layers 128 are formed using one of CVD, PVD, ALD, some other suitable deposition process, or a combination of the foregoing.

As shown in the cross-sectional view 1100 of FIG. 11, a first barrier layer 122 and a first wire level 124 are formed in the additional dielectric layers 128. In some embodiments, the first barrier layer 122 and the first wire level 124 are formed using multiple etching processes to form openings. The openings are then filled with a conformal barrier layer (not shown) and a conformal conductive layer (not shown). A planarization process (e.g., a chemical mechanical planarization (CMP) process) is then performed, removing portions of the conformal barrier layer and the conformal conductive layer that are above an upper surface of the additional dielectric layers 128.

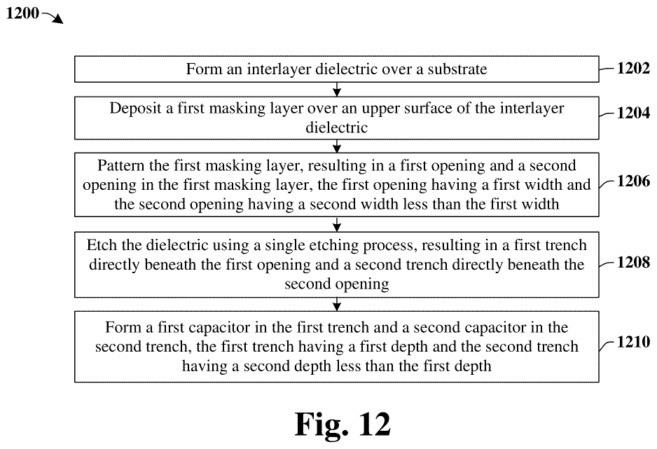

FIG. 12 illustrates a flow diagram of some embodiments of a method of forming an integrated chip having a plurality of capacitors with bottom electrodes of different depths and widths.

While method 1200 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 1202, an interlayer dielectric is formed over a substrate. FIG. 5 illustrates a cross-sectional view 500 of some embodiments corresponding to act 1202.

At 1204, a photoresist is deposited over an upper surface of the interlayer dielectric. FIG. 5 illustrates a cross-sectional view 500 of some embodiments corresponding to act 1204.

At 1206, the photoresist is patterned, resulting in a first opening and a second opening in the photoresist, the first opening having a first width and the second opening having a second width less than the first width. FIG. 6 illustrates a cross-sectional view 600 of some embodiments corresponding to act 1206.

At 1208, the dielectric is etched using a single etching process, resulting in a first trench directly beneath the first opening and a second trench directly beneath the second opening. FIG. 7 illustrates a cross-sectional view 700 of some embodiments corresponding to act 1208.

At 1210, a first capacitor is formed in the first trench and a second capacitor is formed in the second trench, the first trench having a first depth and the second trench having a second depth less than the first depth. FIGS. 7-11 illustrates cross-sectional views 700-1100 of some embodiments corresponding to act 1210.

Therefore, the present disclosure relates to a new method of forming an integrated chip having a plurality of capacitors with bottom electrode structures of different depths and widths.

Accordingly, in some embodiments, the present disclosure relates to an integrated device, including a substrate; an interconnect structure disposed over the substrate, the interconnect structure including an interlayer dielectric; a first bottom electrode structure disposed in the interlayer dielectric, the first bottom electrode structure having a first width as measured between outer sidewalls of the first bottom electrode structure and a first depth as measured from an upper surface of the interlayer dielectric; and a second bottom electrode structure disposed in the interlayer dielectric and spaced apart from the first bottom electrode structure, the second bottom electrode structure having a second width as measured between outer sidewalls of the second bottom electrode structure and a second depth as measured from the upper surface of the interlayer dielectric; where the first width is greater than the second width and the first depth is greater than the second depth.

In other embodiments, the present disclosure relates to a capacitor array, including a plurality of capacitors arranged in an interconnect structure, the capacitors comprising horizontal portions of bottom electrodes arranged at a first elevation; a plurality of bottom electrode structures of the plurality of capacitors extending from the horizontal portions of the bottom electrodes, the plurality of bottom electrode structures extending to a plurality of different depths measured from the first elevation, including a least depth and a greatest depth of the plurality of different depths, and having a plurality of different widths measured between outer sidewalls of the plurality of bottom electrode structures, including a least width and a greatest width of the plurality of different widths; where a first bottom electrode structure of the plurality of bottom electrode structures has the least depth and the least width, and wherein bottom electrode structures of the plurality of bottom electrode structures with progressively greater depths up to the greatest depth have progressively greater widths up to the greatest width.

In yet other embodiments, the present disclosure relates to a method of forming capacitors in an integrated device, including forming a dielectric over a substrate; depositing a photoresist over an upper surface of the dielectric; patterning the photoresist, resulting in a first opening and a second opening in the photoresist, the first opening having a first width and the second opening having a second width less than the first width; etching the dielectric using a single etching process, resulting in a first trench directly beneath the first opening and a second trench directly beneath the second opening; and forming a first capacitor in the first trench and a second capacitor in the second trench, the first trench having a first depth and the second trench having a second depth less than the first depth.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate;
an interconnect structure disposed over the substrate, the interconnect structure including an interlayer dielectric;
a first bottom electrode structure disposed in the interlayer dielectric, wherein the first bottom electrode structure has a first width measured between outer sidewalls of the first bottom electrode structure and has a first depth as measured from an upper surface of the interlayer dielectric; and
a second bottom electrode structure disposed in the interlayer dielectric and spaced apart from the first bottom electrode structure, wherein the second bottom electrode structure has a second width measured between outer sidewalls of the second bottom electrode structure and has a second depth as measured from the upper surface of the interlayer dielectric;
wherein the first width is greater than the second width and the first depth is greater than the second depth.

2. The integrated device of claim 1, wherein the first bottom electrode structure is electrically coupled to the second bottom electrode structure by a metal line extending from the first bottom electrode structure to the second bottom electrode structure across the upper surface of the interlayer dielectric.

3. The integrated device if claim 1, further comprising:
a third bottom electrode structure disposed in the interlayer dielectric and electrically coupled to the first bottom electrode structure by a metal line, wherein the third bottom electrode structure has a third width as measured between outer sidewalls of the third bottom electrode structure and has a third depth as measured from the upper surface of the interlayer dielectric;
wherein the third width is substantially equal to the first width and the third depth is substantially equal to the first depth.

4. The integrated device of claim 1, further comprising:
a first via electrically coupled to the first bottom electrode structure and extending over the first bottom electrode structure.

5. The integrated device of claim 1, further comprising:
a first via electrically coupled to the first bottom electrode structure and extending under the first bottom electrode structure.

6. The integrated device of claim 1, further comprising:
a hard mask surrounding the outer sidewalls of the first bottom electrode structure.

7. A capacitor array, comprising:
a plurality of capacitors arranged in an interconnect structure, wherein the capacitors comprise horizontal portions of bottom electrodes arranged at a first elevation; and
a plurality of bottom electrode structures of the plurality of capacitors extending from the horizontal portions of the bottom electrodes, the plurality of bottom electrode structures extending to a plurality of different depths measured from the first elevation, comprising a least depth and a greatest depth of the plurality of different depths, and having a plurality of different widths measured between outer sidewalls of the plurality of bottom electrode structures, comprising a least width and a greatest width of the plurality of different widths;
wherein a first bottom electrode structure of the plurality of bottom electrode structures has the least depth and the least width, and wherein bottom electrode structures of the plurality of bottom electrode structures with progressively greater widths up to the greatest width have progressively greater depths up to the greatest depth.

8. The capacitor array of claim 7, wherein the plurality of capacitors further comprise a plurality of top electrodes extending into the plurality of bottom electrode structures.

9. The capacitor array of claim 7, further comprising a hard mask contacting the horizontal portions and the plurality of bottom electrode structures of the plurality of capacitors.

10. The capacitor array of claim 7, wherein a capacitor of the plurality of capacitors has multiple bottom electrode structures of the plurality of bottom electrode structures.

11. The capacitor array of claim 7, wherein a first portion of the plurality of bottom electrode structures extend through one or more etch stop layers, and a second portion of the plurality of bottom electrode structures have bottom surfaces over the one or more etch stop layers.

12. The capacitor array of claim 7, wherein a second bottom electrode structure of the plurality of bottom electrode structures has a median depth of the plurality of different depths and a median width of the plurality of different widths.

13. A method of forming capacitors in an integrated device, comprising:
forming an interlayer dielectric over a substrate;
depositing a first masking layer over an upper surface of the interlayer dielectric;
patterning the first masking layer, resulting in a first opening and a second opening in the first masking layer, the first opening having a first width and the second opening having a second width less than the first width;
etching the interlayer dielectric using a single etching process, resulting in a first trench directly beneath the first opening and a second trench directly beneath the second opening; and
forming a first capacitor in the first trench and a second capacitor in the second trench, the first trench having a first depth and the second trench having a second depth less than the first depth.

14. The method of claim 13, further comprising:
depositing a hard mask over the interlayer dielectric; and
patterning the hard mask, resulting in a first opening and a second opening in the hard mask, the first opening having the first width and the second opening having the second width.

15. The method of claim 13, wherein the single etching process etches the first trench and the second trench.

16. The method of claim 13, further comprising:
forming a third opening having a third width when patterning the first masking layer; and
forming a third trench during the single etching process, the third trench directly beneath the third opening in the first masking layer, where the first capacitor is formed in the third trench in addition to the first trench.

17. The method of claim 13, wherein the first trench extends through one or more etch stop layers within the interlayer dielectric, and wherein the second trench does not extend through the one or more etch stop layers within the interlayer dielectric.

18. The method of claim 13, further comprising:
forming a first plurality of wires within the interlayer dielectric before depositing the first masking layer; and
forming a second plurality of wires after forming the first capacitor and the second capacitor, where bottom electrodes of the first capacitor and the second capacitor are coupled to the first plurality of wires and top electrodes of the first capacitor and the second capacitor are coupled to the second plurality of wires.

19. The method of claim 13, further comprising:
forming a first plurality of vias after forming the first capacitor and the second capacitor; and
forming a first plurality of wires, wherein bottom electrodes of the first capacitor and the second capacitor are coupled to the first plurality of wires by the first plurality of vias and top electrodes of the first capacitor and the second capacitor are coupled to the first plurality of wires by the first plurality of vias.

20. The method of claim 13, wherein forming the first capacitor and the second capacitor further comprises forming a first horizontal portion of the first capacitor and a second horizontal portion of the second capacitor, and wherein the first horizontal portion has a first area and the second horizontal portion has a second area different from the first area.
